(19) United States
(12) Patent Application Publication
(10) Pub. No.: US 2024/0318036 A1
(43) Pub. Date: Sep. 26, 2024

(54) POLISHING COMPOSITION, POLISHING METHOD AND METHOD FOR PRODUCING SEMICONDUCTOR SUBSTRATE

(71) Applicant: FUJIMI INCORPORATED, Aichi (JP)

(72) Inventor: Ryota MAE, Aichi (JP)

(21) Appl. No.: 18/605,224

(22) Filed: Mar. 14, 2024

(30) Foreign Application Priority Data
Mar. 23, 2023 (JP) 2023-046310

(51) Int. Cl. C09G 1/02

(52) U.S. Cl. CPC C09G 1/02

(57) ABSTRACT

To provide a polishing composition that can polish silicon nitride film at a high polishing removal rate and suppress the polishing removal rate for polycrystalline silicon film.

A polishing composition containing abrasive grains having a negative zeta potential in the polishing composition, and a polyalkylene oxide compound represented by formula (1); and having a pH of less than 7.

### CROSS-REFERENCE TO RELATED APPLICATION

The entire disclosure of Japanese Patent Application 2023-046310 filed on Mar. 23, 2023, is incorporated herein by reference in its entirety.

### BACKGROUND OF THE INVENTION

### Field of the Invention

The present invention relates to a polishing composition, a polishing method, and a method for producing a semiconductor substrate.

### Description of the Related Art

In recent years, a so-called chemical mechanical polishing (CMP) technique for polishing and flattening a semiconductor substrate in producing a device is used in accordance with multilayer wiring on a surface of a semiconductor substrate.

The CMP has been applied to various steps in semiconductor manufacturing, and one aspect thereof is, for example, its application to the gate formation step in transistor fabrication. During transistor fabrication, materials such as metal, silicon, silicon oxide, polycrystalline silicon, and silicon nitride may be polished, and there is a requirement to polish each material at a high polishing removal rate in order to improve productivity. For example, there is a requirement to polish silicon nitride, whose chemical reactivity is poor, at a high polishing removal rate. To meet such a requirement, for example, Japanese Patent Laid-Open No. 2012-040671 (corresponding U.S. Patent Application: US2013/146804A) discloses that silicon nitride can be polished at a high polishing removal rate with a polishing composition containing a colloidal silica having sulfonic acid immobilized thereon and having a pH of 6 or less.

### SUMMARY OF INVENTION

In studying the application of CMP to various steps in semiconductor manufacturing, the inventors of the present invention have found that, in some cases, polishing silicon nitride film at a high polishing removal rate in the presence of polycrystalline silicon film is preferable from the viewpoint of manufacturing. Meanwhile, the inventors have found that, for polycrystalline silicon film, it is preferable in some cases to keep the polishing removal rate as low as possible from the viewpoint of manufacturing. However, there is still no polishing composition that can polish silicon nitride film at a high polishing removal rate and suppress the polishing removal rate for polycrystalline silicon film.

Accordingly, an object of the present invention is to provide a polishing composition that can polish silicon nitride film at a high polishing removal rate and suppress the polishing removal rate for polycrystalline silicon film.

The inventors of the present invention have intensively studied to solve the above problems. As a result, the inventors have discovered that the above problems can be solved by a polishing composition containing abrasive grains having a negative zeta potential in the polishing composition, and a polyalkylene oxide compound represented by the following formula (1):

[Formula 1]

R¹—(O—R²)ₙ—OR³ (1)

wherein R¹ and R³ each independently represent a hydrogen atom or an alkyl group having 1 or more and 20 or less carbon atoms; R² represents an alkylene group having 4 carbon atoms; and n is an average number of moles of an alkyleneoxy group (O—R²) added and represents a number of 3 or more and 100 or less; and having a pH of less than 7 and thus have completed the present invention.

### DETAILED DESCRIPTION OF THE PREFERRED EMBODIMENTS

Hereinafter, embodiments of the present invention will be described in detail. The embodiments shown here are examples to embody the technical concept of the present invention and are not intended to limit the present invention. Hence, all other practicable forms, methods of use, and techniques of operation, etc., which may be contemplated by those skilled in the art, etc., to the extent not departing from the gist of the present invention, are included in the scope and gist of the present invention, as well as in the scope of the present invention described in the claims and its equivalents. The embodiments described in this specification can be optionally combined to make other embodiments. Also, in this specification, unless otherwise specified, operation and measurement of physical properties, etc., are performed under conditions of room temperature (20° C. or higher and 25° C. or lower)/relative humidity of 40% RH or more and 60% RH or less.

One aspect of the present invention is a polishing composition containing abrasive grains having a negative zeta potential in the polishing composition, and a polyalkylene oxide compound which has an oxyalkylene group having 4 carbon atoms as a repeating unit; and having a pH of less than 7. Such a polishing composition can polish silicon nitride film at a high polishing removal rate and suppress the polishing removal rate for polycrystalline silicon film. The inventors of the present invention presume the mechanism by which such effects can be obtained by the present invention as follows. However, the mechanism below is only speculation, and the scope of the present invention is not limited by it.

In one aspect of the present invention, an object to be polished preferably contains at least silicon nitride film and polycrystalline silicon film. The polishing composition of the present aspect provides an effect of polishing the silicon nitride film at a high polishing removal rate and suppressing the polishing removal rate for the polycrystalline silicon film in the object to be polished. In the polishing composition having a pH of less than 7, the abrasive grains having a negative zeta potential are easily adsorbed on the silicon nitride film and the polycrystalline silicon film, which increases the number of abrasive grains present on the surface of the silicon nitride film and the polycrystalline silicon film at the time of polishing. However, if the polishing removal rate for the polycrystalline silicon film is improved, the ratio of the polishing removal rate for the silicon nitride film to the polishing removal rate for the polycrystalline silicon film (polishing removal rate for silicon nitride film/polishing removal rate for polycrystalline silicon film) (hereinafter, also referred to as “polishing selection ratio for silicon nitride”) becomes low. The inventors of the present invention have found that, in an environment with a pH of less than 7, the polishing composition of the present aspect contains a specific polyalkylene oxide compound, thereby suppressing the polishing removal rate for the polycrystalline silicon film while improving or maintaining the polishing removal rate for the silicon nitride film. That is, since the specific polyalkylene oxide compound is a hydrophobic compound, it is considered to be easily adsorbed on the polycrystalline silicon film, which is a hydrophobic film, through the hydrophobic interaction. It is considered that the specific polyalkylene oxide compound is adsorbed on the polycrystalline silicon film and reduces the contact between the abrasive grains and the polycrystalline silicon film, thereby suppressing the polishing removal rate for the polycrystalline silicon film. On the other hand, the specific polyalkylene oxide compound is difficult to be adsorbed on the silicon nitride film since it is a hydrophilic film. As a result, the polishing composition of the present invention is considered to be able to polish the silicon nitride film at a high polishing removal rate and to suppress the polishing removal rate for the polycrystalline silicon film.

As described above, the inventors of the present invention have found that, in the polishing composition having a pH of less than 7, the problems that the silicon nitride film is polished at a high polishing removal rate and the polishing removal rate for the polycrystalline silicon film is suppressed can be solved by the polishing composition containing the abrasive grains having a negative zeta potential and the specific polyalkylene oxide compound.

Note that the above mechanism is based on speculation, and the present invention is not limited to the above mechanism.

### Object to be Polished

The object to be polished according to the present aspect preferably contains silicon nitride (Si₃N₄) film and polycrystalline silicon (polysilicon) film. That is, the polishing composition according to one preferred embodiment of the present aspect is used for applications where an object to be polished containing silicon nitride film and polycrystalline silicon film is polished.

According to one embodiment of the present aspect, applications of the object to be polished are not limited and examples thereof include semiconductor substrates, solar cell substrates, and liquid crystal display (LCD) TFTs. It is also suitable for their test wafers, monitor wafers, transfer check wafers, dummy wafers, etc.

The object to be polished according to one embodiment may contain other materials in addition to the silicon nitride film and the polycrystalline silicon film. Examples of other materials include silicon oxide, silicon carbonitride (SiₓC_{y}N_{z}), doped polycrystalline silicon (doped polysilicon), undoped amorphous silicon, metals, and SiGe.

Examples of a film containing silicon oxide include a TEOS (Tetraethyl Orthosilicate)-type silicon oxide film (hereinafter, also simply referred to as “TEOS film”) that is formed using tetraethyl orthosilicate as a precursor, a HDP (High Density Plasma) film, an USG (Undoped Silicate Glass) film, a PSG (Phosphorus Silicate Glass) film, a BPSG (Boron-Phospho Silicate Glass) film, and a RTO (Rapid Thermal Oxidation) film.

Examples of a metal-containing film include tungsten (W) film, titanium nitride (TiN) film, ruthenium (Ru) film, platinum (Pt) film, silver (Ag) film, gold (Au) film, hafnium (Hf) film, cobalt (Co) film, palladium (Pd), iridium (Ir), osmium (Os), nickel (Ni) film, copper (Cu) film, aluminum (Al) film, and tantalum (Ta) film.

Furthermore, the shape of the object to be polished is not limited. In one embodiment of the present aspect, the polishing composition can be preferably applied to polishing of an object to be polished having a planar surface, such as a plate or a polyhedron.

### Abrasive Grains

The polishing composition according to the present aspect contains abrasive grains. The abrasive grains contained in the polishing composition according to the present invention have a negative zeta potential. If the zeta potential of the abrasive grains is 0 mV or positive at a pH of less than 7, the polishing removal rate for the silicon nitride film becomes low, resulting in a lower polishing removal rate for the silicon nitride film compared to the polishing removal rate for the polycrystalline silicon film (the polishing selection ratio for silicon nitride becomes low). The abrasive grains are preferably an anion-modified silica (a silica having an anionic group), and more preferably an anion-modified colloidal silica (a colloidal silica having an anionic group). The abrasive grains may be used singly or in combinations of two or more thereof. Further, commercial products of the abrasive grains may be used and synthetic products thereof may also be used.

The polishing composition according to one embodiment preferably contains an anion-modified colloidal silica as the abrasive grains. The anion-modified colloidal silica is a colloidal silica whose surface is modified with anionic group and has the action of mechanically polishing the object to be polished in the polishing composition.

Examples of the anion-modified colloidal silica include a colloidal silica having an anionic group, such as carboxy group, sulfonic acid group, phosphonic acid group, and aluminic acid group, immobilized on the surface thereof. The method for producing such a colloidal silica having an anionic group is not particularly limited, and examples thereof include a method of reacting a silane coupling agent having anionic group at a terminal with a colloidal silica.

As a specific example, if sulfonic acid group is immobilized to the colloidal silica, for example, a method described in “Sulfonic acid-functionalized silica through of thiol groups”, Chem. Commun. 246-247 (2003) can be adopted. More specifically, by coupling a silane coupling agent having thiol groups such as 3-mercaptopropyltrimethoxysilane with the colloidal silica, and subsequently oxidizing the thiol groups with hydrogen peroxide, the colloidal silica with the sulfonic acid group immobilized to its surface can be obtained.

Alternatively, if carboxylic acid group is immobilized to the colloidal silica, for example, a method described in “Novel Silane Coupling Agents Containing a Photolabile 2-Nitrobenzyl Ester for Introduction of a Carboxy Group on the Surface of Silica Gel”, Chemistry Letters, 3, 228-229 (2000)” can be adopted. More specifically, by coupling a silane coupling agent containing photolabile 2-nitrobenzyl ester with the colloidal silica and subsequently irradiating the colloidal silica with light, the colloidal silica with carboxylic acid group immobilized to its surface can be obtained.

The lower limit of the zeta potential of the abrasive grains in the polishing composition is preferably −65 mV or more, more preferably −60 mV or more, further preferably −55 mV or more, particularly preferably −50 mV or more, and most preferably −45 mV or more. Further, the upper limit of the zeta potential of the abrasive grains in the polishing composition is preferably −5 mV or less, more preferably −10 mV or less, further preferably −15 mV or less, particularly preferably −20 mV or less, and most preferably −25 mV or less. Specifically, the zeta potential of the abrasive grains in the polishing composition is preferably −65 mV or more and −5 mV or less, more preferably −60 mV or more and −10 mV or less, further preferably −55 mV or more and −15 mV or less, particularly preferably −50 mV or more and −20 mV or less, and most preferably −45 mV or more and −25 mV or less.

With the abrasive grains having a zeta potential as described above, the silicon nitride film can be polished at a higher polishing removal rate, and the polishing removal rate for the silicon nitride film becomes higher compared to the polishing removal rate for the polycrystalline silicon film (the polishing selection ratio for silicon nitride is more increased).

The average primary particle size of the abrasive grains is preferably 1 nm or more, more preferably 3 nm or more, and further preferably 5 nm or more. As the average primary particle size of the abrasive grains increases, the polishing removal rate for silicon nitride film is improved. Further, the average primary particle size of the abrasive grains is preferably 100 nm or less, more preferably 50 nm or less, and further preferably 30 nm or less. As the average primary particle size of the abrasive grains decreases, the polishing removal rate for the silicon nitride film becomes higher compared to the polishing removal rate for the polycrystalline silicon film (the polishing selection ratio for silicon nitride is more increased).

Specifically, the average primary particle size of the abrasive grains is preferably 1 nm or more and 100 nm or less, more preferably 3 nm or more and 50 nm or less, and further preferably 5 nm or more and 30 nm or less. Note that the average primary particle size of the abrasive grains can be calculated on the basis of the specific surface area (SA) of the abrasive grains, as calculated by a BET method, and the density of the abrasive grains, for example.

Further, the average secondary particle size of the abrasive grains is preferably 15 nm or more, more preferably 20 nm or more, and further preferably 25 nm or more. As the average secondary particle size of the abrasive grains increases, resistance during polishing decreases to enable stable polishing of silicon nitride film. Further, the average secondary particle size of the abrasive grains is preferably 200 nm or less, more preferably 150 nm or less, and further preferably 100 nm or less. As the average secondary particle size of the abrasive grains decreases, the surface area per unit mass of the abrasive grains increases, the frequency of contact with an object to be polished is improved, and the polishing removal rate for silicon nitride film is more improved. Specifically, the average secondary particle size of the abrasive grains is preferably 15 nm or more and 200 nm or less, more preferably 20 nm or more and 150 nm or less, and further preferably 25 nm or more and 100 nm or less. In one embodiment, the average secondary particle size of the abrasive grains is 20 nm or more and less than 70 nm. Note that the average secondary particle size of the abrasive grains can be measured by a dynamic light scattering method as typified by a laser diffraction/scattering method, for example, and specifically a value measured by a method described in Examples is employed.

The ratio of the average secondary particle size to the average primary particle size of the abrasive grains (average secondary particle size/average primary particle size, hereinafter, also referred to as “average degree of association”) is preferably 1.2 or more, more preferably 1.5 or more, further preferably 1.8 or more, particularly preferably 2.0 or more, and most preferably 2.2 or more. As the average degree of association of the abrasive grains increases, the polishing removal rate for the silicon nitride is more improved. Further, the average degree of association of the abrasive grains is preferably 5.5 or less, more preferably 5.0 or less, further preferably 4.5 or less, particularly preferably 4.0 or less, and most preferably 3.5 or less. As the average degree of association of the abrasive grains decreases, the polishing removal rate for the silicon nitride film becomes higher compared to the polishing removal rate for the polycrystalline silicon film (the polishing selection ratio for silicon nitride is more increased). That is, the average degree of association of the abrasive grains is preferably 1.2 or more and 5.5 or less, more preferably 1.5 or more and 5.0 or less, further preferably 1.8 or more and 4.5 or less, particularly preferably 2.0 or more and 4.0 or less, and most preferably 2.2 or more and 3.5 or less.

Note that the average degree of association of the abrasive grains is obtained by dividing the value of the average secondary particle size of the abrasive grains by the value of the average primary particle size of the abrasive grains.

The upper limit of the aspect ratio of the abrasive grains in the polishing composition is not particularly limited, but is preferably 3.5 or less, more preferably 3.0 or less, further preferably 2.5 or less, particularly preferably 2.0 or less, and most preferably 1.5 or less. With the upper limit within such ranges, defects on a surface of an object to be polished can be even more reduced. Note that the aspect ratio is an average value of values, each of which is obtained by dividing the length of the long side of a rectangle by the length of a short side of the rectangle, where the rectangle is the minimum rectangle circumscribing each image of abrasive grains obtained by the use of a scanning electron microscope. The aspect ratio can be found using a general image analysis software. The lower limit of the aspect ratio of the abrasive grains in a polishing composition is not particularly limited, but is preferably 1.1 or more.

The shape of the abrasive grains is not particularly limited, and may be globular or non-globular. Specific examples of the non-globular shape include, but are not particularly limited to, various shapes such as a polygonal columnar shape such as a triangle pole and a square pole, a cylindrical shape, a straw bag shape in which the center part of the cylinder is swollen more than the end parts, a donut shape in which the center part of the disk is hollow, a plate shape, a so-called cocoon type shape having a constriction at the center part, a so-called associated type spherical shape in which a plurality of particles are integrated, a rosary type shape in which a plurality of particles are connected almost in a row, a so-called kompeito shape having a plurality of protrusions on the surface, a rugby ball shape, and a needle type shape that is even thinner than the rugby ball shape.

The sizes of the abrasive grains (such as average primary particle size, average secondary particle size, aspect ratio, and particle shape) can be appropriately controlled by selection and the like of a method for producing the abrasive grains.

In this specification, as the zeta potential of the abrasive grains, a value measured by a method described in Examples is employed. The zeta potential of the abrasive grains can be adjusted using the amount of anionic groups contained in the abrasive grains and the pH or the like of the polishing composition.

In the polishing composition according to the present aspect, the abrasive grains may be used singly or in a mixture of two or more thereof. Further, commercial products of the abrasive grains may be used and synthetic products thereof may also be used.

The content (concentration) of the abrasive grains in the polishing composition is not particularly limited, but is preferably 0.1 mass % or more, more preferably 0.2 mass % or more, further preferably 0.5 mass % or more, and particularly preferably more than 0.5 mass % with respect to the total mass of the polishing composition. Further, the upper limit of the content (concentration) of the abrasive grains in the polishing composition is preferably 10 mass % or less, more preferably 5 mass % or less, further preferably 4 mass % or less, and particularly preferably less than 4 mass % with respect to the total mass of the polishing composition. Specifically, the content (concentration) of the abrasive grains in the polishing composition is preferably 0.1 mass % or more and 10 mass % or less, more preferably 0.2 mass % or more and 5 mass % or less, further preferably 0.5 mass % or more and 4 mass % or less, and particularly preferably more than 0.5 mass % and less than 4 mass % with respect to the total mass of the polishing composition. In one embodiment, the content (concentration) of the abrasive grains in the polishing composition is 2 mass % or more and 10 mass % or less.

With the content of the abrasive grains within such ranges, the polishing removal rate for silicon nitride film is higher compared to the polishing removal rate for polycrystalline silicon film (polishing selection ratio for silicon nitride is more increased). When the polishing composition contains two or more abrasive grains, the content of the abrasive grains refers to the total amount of these abrasive grains.

The polishing composition according to the present aspect may further contain other abrasive grains other than the anion-modified silica, as long as they are abrasive grains having a negative zeta potential in the polishing composition, to such an extent that the effects of the present invention are not impaired. Such other abrasive grains may be any of inorganic particles, organic particles, and organic and inorganic composite particles. Specific examples of the inorganic particles include particles composed of metal oxide such as untreated silica, alumina, ceria, or titania, silicon nitride particles, silicon carbide particles, and boron nitride particles. Specific examples of the organic particles include methyl polymethacrylate (PMMA) particles.

### Polyalkylene Oxide Compound

The polishing composition according to the present invention contains a polyalkylene oxide compound represented by the following formula (1):

[Formula 2]

R¹—(O—R²)ₙ—OR³ (1)

In formula (1), R¹ and R³ each independently represent a hydrogen atom or an alkyl group having 1 or more and 20 or less carbon atoms. The alkyl group having 1 or more and 20 or less carbon atoms may be any of linear alkyl groups, branched alkyl groups, and cyclic alkyl groups having 1 or more and 20 or less carbon atoms, but is preferably a linear alkyl group having 1 or more and 20 or less carbon atoms.

Specific examples of the alkyl group having 1 or more and 20 or less carbon atoms include a methyl group, an ethyl group, a propyl group, an isopropyl group, a n-butyl group, an isobutyl group, a sec-butyl group, a tert-butyl group, a pentyl group, an isopentyl group, a neopentyl group, a 2-ethylhexyl group, a hexyl group, a heptyl group, an octyl group, a 3,7-dimethyloctyl group, a nonyl group, a decyl group, an undecyl group, a dodecyl group (lauryl group), a tridecyl group, a tetradecyl group, a pentadecyl group, a hexadecyl group, a heptadecyl group, and an octadecyl group.

As for R¹ and R³, at least one of them is preferably a hydrogen atom from the viewpoint of polishing removal rate for silicon nitride, and it is preferable that both of them are hydrogen atoms.

In formula (1), R² represents an alkylene group having 4 carbon atoms. Examples of the alkylene group having 4 carbon atoms include a n-butylene group (tetramethylene group, —CH₂CH₂CH₂CH₂— group), a 1-methyltrimethylene group (—CH(CH₃)CH₂CH₂— group), a 2-methyl trimethylene group (—CH₂CH(CH₃)CH₂— group), a 1-ethylethylene group (—C(C₂H₅)CH₂), a 1,1-dimethylethylene group (—C(CH₃)₂CH₂— group), an ethylmethylmethylene group (—C(CH₃)(C₂H₅)—), and a propylmethylene group (—C(C₃H₇)—). Of these, a n-butylene group (—CH₂CH₂CH₂CH₂— group) and a 1-methyltrimethylene group (—CH(CH₃)CH₂CH₂— group) are preferable. The compound of formula (1) is, for example, a compound having a tetramethylene oxide chain as “—(O—R²)ₙ—” in the case of R² being a n-butylene group, and a compound having a polybutylene oxide chain (poly-1-methyltrimethylene oxide chain) as “—(O—R²)ₙ—” in the case of R² being a 1-methyltrimethylene group.

In formula (1), n is the average number of moles of the alkyleneoxy group (O—R²) added and represents a number of 3 or more and 100 or less. n is preferably 3 or more and 60 or less, more preferably 5 or more and 50 or less, further preferably 5 or more and 30 or less, and particularly preferably 5 or more and 25 or less. When n is within the above range, the polishing removal rate for the silicon nitride film becomes higher compared to the polishing removal rate for the polycrystalline silicon film (the polishing selection ratio for silicon nitride is more increased).

The weight average molecular weight (Mw) of the polyalkylene oxide compound represented by formula (1) is preferably 100 or more and 6000 or less, more preferably 150 or more and 5000 or less, further preferably 200 or more and 4000 or less, particularly preferably 250 or more and 3500 or less, and most preferably 300 or more and less than 3000. In one embodiment, the weight average molecular weight of the polyalkylene oxide compound is less than 3000. When the weight average molecular weight of the polyalkylene oxide compound is within the above range, the polishing removal rate for the silicon nitride film becomes higher compared to the polishing removal rate for the polycrystalline silicon film (the polishing selection ratio for silicon nitride is more increased). Here, the weight average molecular weight of the polyalkylene oxide compound is measured by gel permeation chromatography (GPC) using polystyrene as a reference material.

Specific examples of the polyalkylene oxide compound include polytetramethylene oxide and polybutylene oxide (poly-1-methyltrimethylene oxide). Of these, polytetramethylene oxide is preferable as the polyalkylene oxide compound from the viewpoint of polishing selection ratio for silicon nitride.

In the polishing composition according to the present aspect, the polyalkylene oxide compound may be used singly or in a mixture of two or more thereof. Further, commercial products of the polyalkylene oxide compound may be used and synthetic products thereof may also be used.

The content (concentration) of the polyalkylene oxide compound in the polishing composition is not particularly limited, but is preferably 0.0001 mass % or more, more preferably 0.0005 mass % or more, further preferably 0.001 mass % or more, particularly preferably 0.003 mass % or more, and most preferably 0.005 mass % or more with respect to the total mass of the polishing composition. Further, the upper limit of the content (concentration) of the polyalkylene oxide compound in the polishing composition is preferably 5 mass % or less, more preferably 1 mass % or less, further preferably 0.5 mass % or less, particularly preferably 0.2 mass % or less, and most preferably 0.1 mass % or less with respect to the total mass of the polishing composition. Specifically, the content (concentration) of the polyalkylene oxide compound is preferably 0.0001 mass % or more and 5 mass % or less, more preferably 0.0005 mass % or more and 1 mass % or less, further preferably 0.001 mass % or more and 0.5 mass % or less, particularly preferably 0.003 mass % or more and 0.2 mass % or less, and most preferably 0.005 mass % or more and 0.1 mass % or less with respect to the total mass of the polishing composition.

When the content (concentration) of the polyalkylene oxide compound is within such ranges, the polishing removal rate for the silicon nitride film becomes higher compared to the polishing removal rate for the polycrystalline silicon film (the polishing selection ratio for silicon nitride is more increased). In the case of the polishing composition containing two or more polyalkylene oxide compounds, the content (concentration) of the polyalkylene oxide compounds refers to the total amount of these polyalkylene oxide compounds.

### pH and pH Adjusting Agent

The pH of the polishing composition according to the present aspect is less than 7. If the pH of the polishing composition is 7 or more, the polishing removal rate for the polycrystalline silicon film becomes high, and the polishing selection ratio for silicon nitride becomes low. In one embodiment, the pH of the polishing composition is more than 1. Hence, in one embodiment, the pH of the polishing composition is more than 1 and less than 7. Further, the pH of the polishing composition is preferably 1.5 or more, more preferably 2.0 or more, further preferably 2.5 or more, particularly preferably 3.0 or more, and most preferably 3.5 or more. The pH of the polishing composition is preferably 6.5 or less, more preferably 6.0 or less, further preferably 5.5 or less, particularly preferably 5.0 or less, and most preferably 4.5 or less. Specifically, the pH of the polishing composition is preferably 1.5 or more and 6.5 or less, more preferably 2.0 or more and 6.0 or less, further preferably 2.5 or more and 5.5 or less, particularly preferably 3.0 or more and 5.0 or less, and most preferably 3.5 or more and 4.5 or less. In one embodiment, the pH of the polishing composition is 2 or more and 5 or less. When the pH of the polishing composition is within such ranges, the polishing removal rate for the silicon nitride film becomes higher compared to the polishing removal rate for the polycrystalline silicon (the polishing selection ratio for silicon nitride is more increased).

The polishing composition of the present aspect may contain a pH adjusting agent in order to adjust the pH to less than 7. Examples of the pH adjusting agent include an inorganic acid, an organic acid, and an alkali. These pH adjusting agents may be used singly or in combinations of two or more thereof.

Specific examples of the inorganic acid that can be used as the pH adjusting agent include hydrochloric acid, sulfuric acid, nitric acid, hydrofluoric acid, boric acid, carbonic acid, hypophosphorous acid, phosphorous acid, and phosphoric acid. Of these, hydrochloric acid, sulfuric acid, nitric acid, or phosphoric acid is preferable, and nitric acid is more preferable. The use of nitric acid as the pH adjusting agent can improve the polishing selectivity for the silicon nitride film, and can suitably improve the polishing removal rate for the silicon nitride film.

Specific examples of the organic acid that can be used as the pH adjusting agent include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, phenoxyacetic acid, methanesulfonic acid, ethanesulfonic acid, 10-camphorsulfonic acid, and isethionic acid.

A salt, such as an alkali metal salt, of the inorganic acid or organic acid may be used as the pH adjusting agent instead of the inorganic acid or organic acid or in combination with the inorganic acid or organic acid. In the case of a combination of a weak acid and a strong base, a strong acid and a weak base, or a weak acid and a weak base, a pH buffering effect can be expected.

Specific examples of the alkali that can be used as the pH adjusting agent include ammonia, a hydroxide of a group 1 element (for example, sodium hydroxide and potassium hydroxide), a hydroxide of a group 2 element (for example, barium hydroxide), a quaternary ammonium hydroxide (for example, tetramethylammonium hydroxide), and a salt thereof. Examples of the salt include carbonate, hydrogen carbonate, sulfate, and acetate.

In one embodiment, the polishing composition according to the present aspect further contains one or more pH adjusting agents selected from organic acids and inorganic acids. Specifically, in one embodiment, the polishing composition according to the present aspect further contains an organic acid or an inorganic acid as the pH adjusting agent. The containment of an organic acid or an inorganic acid as the pH adjusting agent can improve the polishing selectivity for the silicon nitride film, and can suitably improve the polishing removal rate for the silicon nitride film.

The content of the pH adjusting agent can be selected by adjusting it as appropriate to such an extent that the effects of the present invention are achieved. Note that the pH of the polishing composition can be measured with, for example, a PH meter (for example, a pH meter (model number: LAQUA) manufactured by HORIBA, Ltd).

### Dispersing Medium

The polishing composition according to the present aspect preferably contains a dispersing medium for dispersing each component. Examples of the dispersing medium can include water, alcohols such as methanol, ethanol, and ethylene glycol, ketones such as acetone, and mixtures thereof. Of these, water is preferable as the dispersing medium. Specifically, according to a preferred embodiment of the present aspect, examples of the dispersing medium include water. According to a more preferred embodiment of the present aspect, the dispersing medium is substantially composed of water. Note that the above “substantially” is intended to mean that a dispersing medium other than water can be contained as long as the effects of the present aspect can be achieved. More specifically, the dispersing medium is composed of preferably 90 mass % or more and 100 mass % or less of water and 0 mass % or more and 10 mass % or less of a dispersing medium other than water, and more preferably 99 mass % or more and 100 mass % or less of water and 0 mass % or more and 1 mass % or less of a dispersing medium other than water. Most preferably, the dispersing medium is water.

Water containing impurities in an amount as low as possible is preferable as the dispersing medium from the viewpoint of not inhibiting the action of components contained in the polishing composition. Specifically, pure water or ultra-pure water, which is obtained by removing foreign matter through a filter after removal of impurity ions using an ion exchange resin, or distilled water is more preferable.

### Other Components

The polishing composition according to the present invention may further contain known additives such as a complexing agent, an antiseptic agent, an antifungal agent, an oxidizing agent, a surfactant other than the polyalkylene oxide compound represented by formula (1), a water-soluble polymer other than the polyalkylene oxide compound represented by formula (1), and a dissolution aid, which can be used for the polishing composition, to such an extent that the effects of the present invention are not impaired. The polishing composition according to the present invention has a pH of less than 7. For this reason, it is more preferable that the polishing composition contains an antifungal agent. Specifically, in one embodiment of the present aspect, the polishing composition is substantially constituted by abrasive grains, a polyalkylene oxide compound, and a dispersing medium, as well as at least one selected from the group consisting of a pH adjusting agent, a dissolution aid, and an antifungal agent. In one embodiment of the present invention, the polishing composition is substantially constituted by abrasive grains, a polyalkylene oxide compound, and a dispersing medium, as well as at least one selected from the group consisting of a pH adjusting agent, a dissolution aid, and an antifungal agent. Here, “the polishing composition is substantially constituted by abrasive grains, a polyalkylene oxide compound, and a dispersing medium, as well as at least one selected from the group consisting of a pH adjusting agent, a dissolution aid, and an antifungal agent” is intended to mean that the total content of the abrasive grains, the polyalkylene oxide compound, the dispersing medium, the pH adjusting agent, the dissolution aid, and the antifungal agent is more than 99 mass % (upper limit: 100 mass %) with respect to the polishing composition. Preferably, the polishing composition is constituted by abrasive grains, a polyalkylene oxide compound, and a dispersing medium, as well as at least one selected from the group consisting of a pH adjusting agent, a dissolution aid, and an antifungal agent (the above total content=100 mass %).

The antifungal agent (antiseptic agent) is not particularly limited, and can be appropriately selected depending on the desired application and purpose. Specific examples thereof include isothiazoline-based antiseptic agents such as 1,2-benzoisothiazol-3(2H)-one (BIT), 2-methyl-4-isothiazolin-3-one, and 5-chloro-2-methyl-4-isothiazolin-3-one, and phenoxyethanol.

The dissolution aid is a substance that is allowed to coexist when dissolving a water-soluble polymer in a dispersing medium (solvent) to improve the solubility of the water-soluble polymer. The polishing composition according to one embodiment of the present invention may further contain a dissolution aid.

Examples of the dissolution aid include alcohol compounds such as methanol, ethanol, 1-propanol, 2-propanol, ethylene glycol, and propylene glycol; ether compounds such as diethylene glycol diethyl ether, 2-methoxyethanol, 2-ethoxyethanol, diethylene glycol, diethylene glycol monomethyl ether, diethylene glycol monoethyl ether, diethylene glycol monobutyl ether, triethylene glycol, triethylene glycol monomethyl ether, tetraethylene glycol, dipropylene glycol, dipropylene glycol monomethyl ether, dipropylene glycol monoethyl ether, tripropylene glycol monomethyl ether, diacetone alcohol, 2-methoxyethyl acetate, 2-ethoxyethyl acetate, and diethylene glycol monoethyl ether acetate; and ketone compounds such as acetone, methyl ethyl ketone, acetylacetone, and cyclohexanone. One dissolution aid can be used, or two or more thereof may be used in a mixture.

### Polishing Method and Method for Producing Semiconductor Substrate

The polishing composition according to the present aspect is suitably used for polishing an object to be polished containing silicon nitride and polycrystalline silicon, for example. Hence, another aspect of the present invention provides a polishing method, which involves polishing an object to be polished containing silicon nitride and polycrystalline silicon using the polishing composition according to the present aspect. Further, another aspect of the present invention provides a method for producing a semiconductor substrate, which involves polishing a semiconductor substrate containing silicon nitride and polycrystalline silicon using the polishing composition according to the present aspect. Further, another aspect of the present invention provides a method for producing a semiconductor substrate, which includes a step of polishing a semiconductor substrate containing silicon nitride and polycrystalline silicon by the polishing method according to the present aspect.

As a polishing apparatus, it is possible to use a general polishing apparatus including a holder for holding a substrate or the like having an object to be polished, a motor having a changeable rotational speed or the like fitted thereto, and a platen to which a polishing pad (polishing cloth) can be attached.

As the polishing pad, general nonwoven fabric, polyurethane, a porous fluororesin, or the like can be used without any particular limitation. The polishing pad is preferably grooved such that a polishing liquid can be stored therein.

Regarding polishing conditions, for example, the rotational speed of a platen and a carrier is preferably 10 rpm (0.17 s⁻¹) or more and 500 rpm (8.33 s⁻¹) or less. The pressure (polishing pressure) applied to a substrate having an object to be polished is preferably 0.5 psi (3.4 kPa) or more and 10 psi (68.9 kPa).

A method for feeding the polishing composition to a polishing pad is also not particularly limited. For example, a method for continuously feeding the polishing composition using a pump or the like is employed. The feed rate is not limited, but a surface of the polishing pad is preferably covered all the time with the polishing composition according to the present invention.

After completion of polishing, the substrate is cleaned in running water, water droplets adhered onto the substrate are removed using a spin dryer or the like for drying, and thus the substrate is obtained.

The polishing composition according to the present aspect may be of a single-fluid type or multi-fluid type including double-fluid type. Further, the polishing composition according to the present aspect may be prepared by, for example, diluting 3 or more times (or 5 or more times, for example) an undiluted solution of the polishing composition using a diluent such as water.

### Polishing Removal Rate Suppressing Agent

When polishing a semiconductor substrate containing silicon nitride and polycrystalline silicon, the polishing composition according to the present aspect selectively polishes silicon nitride and suppresses polishing of polycrystalline silicon. Hence, according to another aspect of the present invention, provided is a polishing removal rate suppressing agent for polycrystalline silicon film, containing a polyalkylene oxide compound represented by the following formula (1):

[Formula 3]

R¹—(O—R²)ₙ—OR³ (1)

wherein R¹ and R³ each independently represent a hydrogen atom or an alkyl group having 1 or more and 20 or less carbon atoms; R² represents an alkylene group having 4 carbon atoms; and n is an average number of moles of an alkyleneoxy group (O—R²) added and represents a number of 3 or more and 100 or less.

### Polishing Removal Rate

When the polishing composition according to the present aspect is used for polishing, the polishing removal rate for silicon nitride film is preferably 150 Å/min or more and 5000 Å/min or less, more preferably 200 Å/min or more and 2500 Å/min or less, further preferably 220 Å/min or more and 2000 Å/min or less, and particularly preferably 250 Å/min or more and 1500 Å/min or less. When the polishing composition according to the present invention is used for polishing, the polishing removal rate for polycrystalline silicon film is preferably 100 Å/min or less, more preferably 50 Å/min or less, further preferably 45 Å/min or less, and particularly preferably 40 Å/min or less. The lower limit of the polishing removal rate for polycrystalline silicon film is not particularly limited, but is 5 Å/min or more for practical use.

### Polishing Selection Ratio

When the polishing composition according to the present aspect is used in applications where an object to be polished containing silicon nitride and polycrystalline silicon is polished, the ratio of the polishing removal rate for silicon nitride to the polishing removal rate for polycrystalline silicon (polishing removal rate for silicon nitride/polishing removal rate for polycrystalline silicon) is preferably 10 or more, more preferably 12 or more, further preferably 15 or more, particularly preferably 20 or more, and most preferably 30 or more.

The embodiments of the present invention are described in detail above, but are given for explanatory and illustrative purposes only, and are not limited. The scope of the present invention should be obviously construed on the basis of the attached claims.

The present invention encompasses following aspects and embodiments.

[1] A polishing composition comprising; abrasive grains having a negative zeta potential in the polishing composition, and a polyalkylene oxide compound represented by the following formula (1):

[Formula 4]

R¹—(O—R²)ₙ—OR³ (1)

wherein R¹ and R³ each independently represent a hydrogen atom or an alkyl group having 1 or more and 20 or less carbon atoms; R² represents an alkylene group having 4 carbon atoms; and n is an average number of moles of an alkyleneoxy group (O—R²) added and represents a number of 3 or more and 100 or less;
and having a pH of less than 7.

[2] The polishing composition according to [1] above, wherein the polyalkylene oxide compound is polytetramethylene oxide.

[3] The polishing composition according to [1] or [2] above, wherein the polyalkylene oxide has a weight average molecular weight of less than 3000.

[4] The polishing composition according to any of [1] to [3] above, wherein the abrasive grains are contained in an amount of 2 mass % or more and 10 mass % or less.

[5] The polishing composition according to any of [1] to [4] above, wherein the abrasive grains have an average secondary particle size of 20 nm or more and less than 70 nm.

[6] The polishing composition according to any of [1] to [5] above, wherein the abrasive grains are an anion-modified colloidal silica.

[7] The polishing composition according to any of [1] to [6] above, wherein the polishing composition has a pH of 2 or more and 5 or less.

[8] The polishing composition according to any of [1] to [7] above, further comprising an organic acid or an inorganic acid as a pH adjusting agent.

[9] The polishing composition according to any of [1] to [8] above, wherein the polishing composition is used for applications where an object to be polished containing silicon nitride and polycrystalline silicon is polished.

[10] The polishing composition according to [9] above, wherein a ratio of a polishing removal rate for the silicon nitride to a polishing removal rate for the polycrystalline silicon (silicon nitride/polycrystalline silicon) is 20 or more.

[11] A polishing method, comprising a step of polishing an object to be polished containing silicon nitride and polycrystalline silicon using the polishing composition according to any of [1] to above.

### EXAMPLES

The present invention will be described in more detail using the following Examples and Comparative Examples, but the technical scope of the present invention is not limited to only the following Examples. Note that unless otherwise specified, “%” and “part(s)” refer to “mass %” and “parts by mass”, respectively.

### Average Primary Particle Size of Abrasive Grains

The average primary particle size of abrasive grains was calculated from the specific surface area of silica particles measured by the BET method using “Flow Sorb II 2300” manufactured by Micromeritics and the density of abrasive grains.

### Average Secondary Particle Size of Abrasive Grains

The average secondary particle size of abrasive grains was measured as volume-mean particle size (arithmetic mean diameter of standard volume; Mv) using a dynamic light scattering particle size·particle size distribution apparatus UPA-UTI151 (manufactured by Nikkiso Co., Ltd.).

### Average Degree of Association of Abrasive Grains

The average degree of association of abrasive grains was calculated by dividing the value of the average secondary particle size of the abrasive grains by the value of the average primary particle size of the abrasive grains.

### Zeta Potential of Abrasive Grains

The zeta potential of abrasive grains in the polishing composition was calculated by subjecting a polishing composition to measurement by a laser doppler method (electrophoretic light scattering method) using Zetasizer Nano manufactured by Malvern Panalytical Ltd., under conditions of the measurement temperature of 25° C., and then analyzing the thus obtained data with Smoluchowski's formula.

### pH of Polishing Composition

Regarding the pH of each polishing composition, 3-point calibration was performed using a glass electrode hydrogen ion concentration indicator (manufactured by HORIBA, Ltd., Model No.: F-23) and standard buffers (phthalate pH buffer pH: 4.01 (25° C.), neutral phosphate pH buffer pH: 6.86 (25° C.), carbonate pH buffer pH: 10.01 (25° C.)), and then the glass electrode was placed in the polishing composition, thereby finding the value stabilized after 2 or more minutes as the pH value.

### Electrical Conductivity of Polishing Composition

The electrical conductivity (EC) of the polishing compositions was measured with a desktop type electrical conductivity meter (manufactured by HORIBA, Ltd., model number: DS-71 LAQUA (R)).

### Preparation of Abrasive Grains

As the anion-modified colloidal silica, anion-modified colloidal silicas of abrasive grains 1 to 3 were prepared by the method described in sulfonate-modified colloidal silica (“Sulfonic acid-functionalized silica through quantitative oxidation of thiol groups”, Chem. Commun. 246-247 (2003)). Note that two colloidal silicas (abrasive grains) were used for the sulfonic acid modification (the abrasive grains 1 and the abrasive grains 2). The following abrasive grains 3 and abrasive grains 4 are the same abrasive grains as the abrasive grains 1, and have different silane coupling agent concentrations (MPS modification amount): 0.24 mass %, 0.6 mass %, and 0.96 mass % with respect to the total mass of silica solids.
Abrasive grains 1: (MPS modification amount 0.6 mass %) average primary particle size: 14 nm, average secondary particle size: 34 nm, average degree of association: 2.4;
Abrasive grains 2: (MPS modification amount 0.6 mass %) average primary particle size: 35 nm, average secondary particle size: 70 nm, average degree of association: 2.0;
Abrasive grains 3: (MPS modification amount 0.24 mass %) average primary particle size: 14 nm, average secondary particle size: 34 nm, average degree of association: 2.4; and
Abrasive grains 4: (MPS modification amount 0.96 mass %) average primary particle size: 14 nm, average secondary particle size: 34 nm, average degree of association: 2.4.

### Preparation of Polishing Composition

### Example 1

The above-obtained abrasive grains 1 (anion-modified colloidal silica) as abrasive grains were added to pure water as a dispersing medium at room temperature (25° C.) so that the final concentration thereof was 3 mass %. Furthermore, 2-methyl-4-isothiazolin-3-one (manufactured by THE DOW CHEMICAL COMPANY) was added as an antifungal agent so that the final concentration was 0.014 mM, thereby obtaining a mixed solution.

Thereafter, polytetramethylene oxide (weight average molecular weight: 1000, manufactured by FUJIFILM Wako Pure Chemical Corporation) was added as the polyalkylene oxide compound to a final concentration of 0.01 mass %, nitric acid (HNO₃) was added as the pH adjusting agent to a pH of 4, and the mixture was stirred and mixed at room temperature (25° C.) for 30 minutes, thereby preparing the polishing composition of Example 1. The pH of the obtained polishing composition was measured to be 4, and the electrical conductivity was 1 mS/cm.

The zeta potential of the abrasive grains 1 (anion-modified colloidal silica) in the obtained polishing composition was measured according to the above method and the result was −40 mV. Moreover, the particle size of the abrasive grains 1 (anion-modified colloidal silica) in the polishing composition was the same as the particle size of the abrasive grains 1 (anion-modified colloidal silica) used.

### Examples 2 to 10, Comparative Examples 1 to 4

Except for changing the type and concentration of each component, and the pH as described in Table 1 below, polishing compositions of Examples 2 to 10 and polishing compositions of Comparative Examples 1 to 4 were prepared in the same manner as in Example 1. The composition of each polishing composition is as shown in Table 1 below. The abrasive grains 1 was used in Examples 3, 6, 7, 9, 10, and Comparative Examples 1 to 4; the abrasive grains 2 in Example 2; the abrasive grains 3 in Example 4; and the abrasive grains 4 in Examples 5 and 8. Further, in Comparative Examples 2 and 3, polyethylene glycol (PEG) was used as the polyalkylene oxide compound (denoted as “PEG200” and “PEG4000” in Table 1). The symbol “-” in Table 1 below indicates that the relevant agent was not used. Note that, when the pH of each polishing composition and the particle size of the abrasive grains in each polishing composition were measured, the results were as shown in Table 1.

### Evaluation

### Evaluation of Polishing Removal Rate of Polishing Composition

Each polishing composition was used to polish the surface of objects to be polished under the following conditions. The following (1) and (2) were prepared as the objects to be polished.

(1) Silicon nitride film (Si₃N₄ film): silicon wafer with 2000 Å thick silicon nitride film formed on the surface (200 mm, blanket wafer); and

(2) Polycrystalline silicon film (poly-Si film): silicon wafer with 5000 Å thick polycrystalline silicon film formed on the surface.

### Polishing Apparatus and Polishing Conditions

Polishing apparatus: manufactured by Applied Materials, Inc., single-side polishing apparatus Mirra CMP 200 mm

Polishing pad: manufactured by NITTA HAAS Incorporated., rigid polyurethane pad IC1010

Polishing pressure: 4.0 psi (1 psi=6894.76 Pa)

Rotational speed of platen: 47 rpm

Rotational speed of head (carrier): 43 rpm

Feed of polishing composition: flowing

Feed rate of polishing composition: 200 ml/minute

Polishing time: 60 seconds

### Calculation of Polishing Removal Rate

The thickness of each object to be polished was measured before and after polishing using an optical film thickness measurement system (ASET-f5x: manufactured by KLA-Tencor Japan Ltd.).

For each object to be polished, the polishing removal rate for each object to be polished was calculated by dividing the difference in film thickness before and after polishing [(thickness before polishing)−(thickness after polishing)] by the polishing time. When the polishing removal rate for the silicon nitride film is 150 Å/min or more, it is indicated that the polishing composition tested can be practically used. For the ratio of the polishing removal rate for the silicon nitride film to the polycrystalline silicon film, when the polishing removal rate for silicon nitride/polishing removal rate for polycrystalline silicon (Si₃N₄/poly-Si in Table 1) is 10 or more (preferably 20 or more), it is indicated that the polishing composition tested can be practically used.

The above evaluation results are shown together in Table 1. In Table 1, the silicon nitride film is denoted as “Si₃N₄” and the polycrystalline silicon film is denoted as “poly-Si”.

TABLE 1

| | Abrasive grains | | | | | | | |
|---|---|---|---|---|---|---|---|---|
| | | Primary | Secondary | | | Polyalkylene oxide compound | | |
| | | particle | particle | | ζ | | | Amount |
| | Concentration | size | size | Association | potential | | | added |
| | Mass % | nm | nm | ratio | mV | Substance name | Mw | Mass % |
| Example 1 | 3 | 14 | 34 | 2.4 | −40 | Polytetramethylene | 1000 | 0.01 |
| | | | | | | oxide | | |
| Example 2 | 3 | 35 | 70 | 2.0 | −40 | Polytetramethylene | 1000 | 0.01 |
| | | | | | | oxide | | |
| Example 3 | 1 | 14 | 34 | 2.4 | −40 | Polytetramethylene | 1000 | 0.01 |
| | | | | | | oxide | | |
| Example 4 | 3 | 14 | 34 | 2.4 | −30 | Polytetramethylene | 1000 | 0.01 |
| | | | | | | oxide | | |
| Example 5 | 3 | 14 | 34 | 2.4 | −45 | Polytetramethylene | 1000 | 0.01 |
| | | | | | | oxide | | |
| Example 6 | 3 | 14 | 34 | 2.4 | −40 | Polytetramethylene | 1000 | 0.01 |
| | | | | | | oxide | | |
| Example 7 | 3 | 14 | 34 | 2.4 | −40 | Polytetramethylene | 1000 | 0.01 |
| | | | | | | oxide | | |
| Example 8 | 3 | 14 | 34 | 2.4 | −45 | Polytetramethylene | 1000 | 0.01 |
| | | | | | | oxide | | |
| Example 9 | 3 | 14 | 34 | 2.4 | −40 | Polytetramethylene | 650 | 0.01 |
| | | | | | | oxide | | |
| Example 10 | 3 | 14 | 34 | 2.4 | −40 | Polytetramethylene | 2000 | 0.01 |
| | | | | | | oxide | | |
| Comparative | 3 | 14 | 34 | 2.4 | −40 | — | — | — |
| Example 1 | | | | | | | | |
| Comparative | 3 | 14 | 34 | 2.4 | −40 | PEG200 | 200 | 0.01 |
| Example 2 | | | | | | | | |
| Comparative | 3 | 14 | 34 | 2.4 | −40 | PPG400 | 400 | 0.01 |
| Example 3 | | | | | | | | |
| Comparative | 3 | 14 | 34 | 2.4 | −40 | Polytetramethylene | 1000 | 0.01 |
| Example 4 | | | | | | oxide | | |

| | | | | Polishing | | | |
|---|---|---|---|---|---|---|---|
| | pH | | | removal | | Polishing | |
| | adjusting | | | rate | | selection | |
| | agent | Physical | | [Å/min] | | ratio | Processing |
| | Substance | properties | | Poly- | | Si₃N₄/Poly- | pressure |
| | name | pH | EC*¹ | Si | Si₃N₄ | Si | [psi] |
| Example 1 | HNO₃ | 4 | 1 | 19 | 925 | 49 | 4 |
| Example 2 | HNO₃ | 4 | 1 | 35 | 867 | 25 | 4 |
| Example 3 | HNO₃ | 4 | 1 | 11 | 498 | 45 | 4 |
| Example 4 | HNO₃ | 4 | 1 | 26 | 754 | 29 | 4 |
| Example 5 | HNO₃ | 4 | 1 | 25 | 931 | 37 | 4 |
| Example 6 | HNO₃ | 2 | 4 | 17 | 980 | 58 | 4 |
| Example 7 | HNO₃ | 3 | 2 | 18 | 956 | 53 | 4 |
| Example 8 | HNO₃ | 5 | 1 | 27 | 721 | 27 | 4 |
| Example 9 | HNO₃ | 4 | 1 | 25 | 927 | 37 | 4 |
| Example 10 | HNO₃ | 4 | 1 | 18 | 672 | 37 | 4 |
| Comparative | HNO₃ | 4 | 1 | 189 | 936 | 5 | 4 |
| Example 1 | | | | | | | |
| Comparative | HNO₃ | 4 | 1 | 127 | 930 | 7 | 4 |
| Example 2 | | | | | | | |
| Comparative | HNO₃ | 4 | 1 | 76 | 918 | 12 | 4 |
| Example 3 | | | | | | | |
| Comparative | — | 7 | 0.2 | 19 | 56 | 3 | 4 |
| Example 4 | | | | | | | |

*¹EC . . . electrical conductivity [mS/cm]

As is evident from Table 1 above, it can be seen that the polishing compositions of Examples can have a high polishing removal rate for the silicon nitride film and suppress the polishing removal rate for the polycrystalline silicon film, thereby providing a high polishing selection ratio for the silicon nitride film. On the other hand, it can be seen that the polishing compositions of Comparative Examples have a low polishing removal rate for the silicon nitride film or have a too high polishing removal rate for the polycrystalline silicon film, etc., and thus do not provide a high polishing selection ratio for the silicon nitride film.

Hence, it can be seen that the polishing compositions according to the present embodiment can polish the silicon nitride film at a high polishing removal rate and suppress the polishing removal rate for the polycrystalline silicon film.

Note that Table 1 above shows the results obtained by separately polishing the object to be polished having silicon nitride film and the object to be polished having polycrystalline silicon film. However, even in the case of polishing an object to be polished having silicon nitride and polycrystalline silicon, it is speculated that the same results of polishing removal rate and polishing selection ratio of polishing removal rate (polishing removal rate for silicon nitride/polishing removal rate for polycrystalline silicon) as in Table 1 above can be obtained.

The present application is based on the Japanese patent application No. 2023-046310 filed on Mar. 23, 2023, and the disclosed content thereof is incorporated herein by reference in their entirety.

1. A polishing composition comprising
abrasive grains having a negative zeta potential in the polishing composition, and
a polyalkylene oxide compound represented by the following formula (1):
[Formula 1]
R¹—(O—R²)ₙ—OR³ (1)
wherein R¹ and R³ each independently represent a hydrogen atom or an alkyl group having 1 or more and 20 or less carbon atoms; R² represents an alkylene group having 4 carbon atoms; and n is an average number of moles of an alkyleneoxy group (O—R²) added and represents a number of 3 or more and 100 or less;
and having a pH of less than 7.

2. The polishing composition according to claim 1, wherein the polyalkylene oxide compound is polytetramethylene oxide.

3. The polishing composition according to claim 1, wherein the polyalkylene oxide has a weight average molecular weight of less than 3000.

4. The polishing composition according to claim 1, wherein the abrasive grains are contained in an amount of 2 mass % or more and 10 mass % or less.

5. The polishing composition according to claim 1, wherein the abrasive grains have an average secondary particle size of 20 nm or more and less than 70 nm.

6. The polishing composition according to claim 1, wherein the abrasive grains are an anion-modified colloidal silica.

7. The polishing composition according to claim 1, wherein the polishing composition has a pH of 2 or more and 5 or less.

8. The polishing composition according to claim 1, further comprising an organic acid or an inorganic acid as a pH adjusting agent.

9. The polishing composition according to claim 1, wherein the polishing composition is used for applications where an object to be polished containing silicon nitride and polycrystalline silicon is polished.

10. The polishing composition according to claim 1, wherein a ratio of a polishing removal rate for the silicon nitride to a polishing removal rate for the polycrystalline silicon (polishing removal rate for silicon nitride/polishing removal rate for polycrystalline silicon) is 20 or more.

11. A polishing method, comprising a step of polishing an object to be polished containing silicon nitride and polycrystalline silicon using the polishing composition according to claim 1.
